(19) United States
(12) Patent Application Publication
(10) Pub. No.: US 2006/0222961 A1
(43) Pub. Date: Oct. 5, 2006

(54) Leaky absorber for extreme ultraviolet mask

(76) Inventor: Pei-Yang Yan, Saratoga, CA (US)

Correspondence Address: INTEL CORPORATION;c/o INTELLEVATE, LLC, P.O. BOX 52050, MINNEAPOLIS, MN, 55402, US

(21) Appl. No.: 11/096,890

(22) Filed: Mar. 31, 2005

(51) Int. Cl. G03C 5/00; G21K 5/00; G03F 1/00

(52) U.S. Cl. 430/5; 378/35; 430/322; 430/323; 430/324

(57) ABSTRACT

The present invention discloses a method of forming a mask including: providing a substrate; forming a multilayer mirror for EUV light over the substrate; forming a leaky absorber for the EUV light over the multilayer mirror; and patterning the leaky absorber into a first region that is strongly reflective and a second region that is weakly reflective. The present invention further discloses an EUV mask including: a substrate; a multilayer mirror located over the substrate, the multilayer mirror having a first region and a second region; and a leaky absorber located over the second region of the multiplayer mirror, the leaky absorber shifting phase of incident light by 180 degrees.

### BACKGROUND OF THE INVENTION

1. Field of the Invention

The present invention relates to the field of semiconductor integrated circuit manufacturing, and more specifically, to a mask and a method of fabricating a mask used in extreme ultraviolet lithography (EUVL).

2. Discussion of Related Art

Continual improvement in photolithography has allowed the shrinkage of semiconductor integrated circuits (IC) to achieve higher density and performance. Deep ultraviolet (DUV) light with a wavelength of 193 nanometers (nm) may be used for optical lithography at the 65 nm node. A further advancement is to use immersion lithography with DUV at the 45 nm node. However, other lithographic technologies may become necessary at the 32 nm node. Possible contenders for Next Generation Lithography (NGL) may include nanoprinting and extreme ultraviolet lithography (EUVL).

EUVL is a leading candidate for NGL, especially for fabrication of high volume ICs. Exposure is performed with extreme ultraviolet (EUV) light with a wavelength of about 10-15 nanometers. EUV light falls in a portion of the electromagnetic spectrum referred to as soft x-ray (2-50 nanometers). Whereas a conventional mask used in DUV lithography is made from fused quartz and is transmissive, virtually all condensed materials are highly absorbing at the EUV wavelength so a reflective mask is required for EUVL.

An EUV step-and-scan tool may use a 4×-reduction projection optical system. Photoresist coated on a wafer may be exposed by stepping fields across the wafer and scanning an arc-shaped region of the EUV mask for each field. The EUV step-and-scan tool may have a 0.35 Numerical Aperture (NA) with 6 imaging mirrors and 2 collection mirrors. A critical dimension (CD) of about 32 nm may be achieved with a depth of focus (DOF) of about 150 nm.

As the CD is reduced further, the absorber stack on the EUV mask may create a shadowing effect during exposure.

Thus, what is needed is an EUV mask to reduce shadowing and a process for fabricating such an EUV mask.

### BRIEF DESCRIPTION OF THE DRAWINGS

FIG. 1 is an illustration of a cross-sectional view of an EUV mask with an absorber layer to reduce shadowing during exposure according to an embodiment of the present invention.

FIGS. 2 A-E are illustrations of a method of forming an EUV mask with an absorber layer to reduce shadowing during exposure according to an embodiment of the present invention.

### DETAILED DESCRIPTION OF THE PRESENT INVENTION

In the following description, numerous details, such as specific materials, dimensions, and processes, are set forth in order to provide a thorough understanding of the present invention. However, one skilled in the art will realize that the invention may be practiced without these particular details. In other instances, well-known semiconductor equipment and processes have not been described in particular detail so as to avoid obscuring the present invention.

The present invention describes various embodiments of a mask for Extreme Ultraviolet (EUV) lithography to reduce shadowing during exposure and a method of forming such an EUV mask.

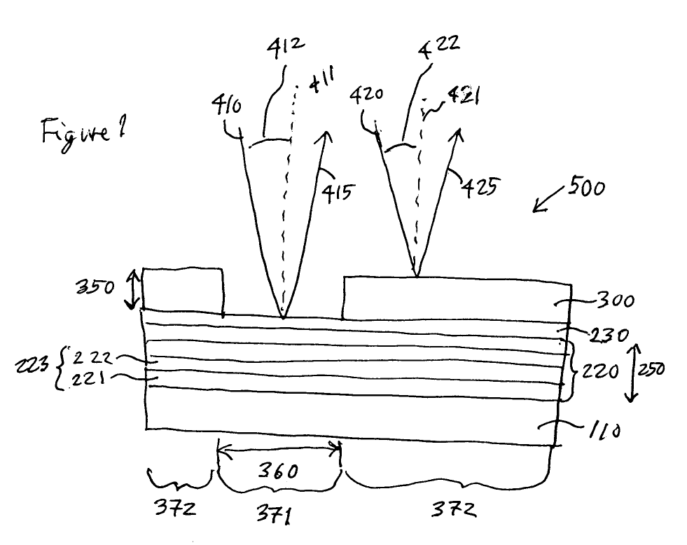

FIG. 1 shows an embodiment of an EUV mask 500 according to the present invention. An EUV mask 500 operates on a principle of a distributed Bragg reflector. A substrate 110 supports a multilayer (ML) mirror 220 of about 20-80 pairs 223 of alternating layers of two materials 221, 222. The two materials 221, 222 have different refractive indices. In order to maximize the difference in electron density, one material 221 has a high atomic number (Z) while the other material 222 has a low Z. The high-Z material 221 acts as a scattering layer and should have minimal thickness at the illumination wavelength. The low-Z material 222 acts as a spacing layer and should have minimal absorption at the illumination wavelength.

Selection of the appropriate materials and thickness 250 for the ML mirror 220 allows the reflected light 415 to add in phase constructively. For example, Molybdenum (Mo) has a Z of 42 while Silicon (Si) has a Z of 14. In order to achieve a resonant reflectivity, the period of each pair 223 in the ML mirror 220 should be approximately half of the illumination wavelength of the incident light 410, 420. For an EUV wavelength of 13.4 nanometers (nm), each pair 223 may be formed from about 2.7 nm thick Mo and about 4.0 nm thick Si. Constructive interference results in a peak normal incidence reflectance of about 60-75% at about 13.4 nm. The bandwidth of the light 415 reflected off the ML mirror 220 is about 1.0 nm and becomes narrower as the number of pairs 223 in the ML mirror 220 increases. However, both reflectance and phase shift saturate beyond about 30-40 pairs 223. The change in reflectance is relatively small for an angle 412, 422 of incidence of 0-8 degrees from the normal angle 411, 421.

Reflectance may be degraded by layer intermixing, interface roughness, and surface oxidation of the ML mirror 220. Layer intermixing is minimized by keeping the processing temperature below about 150 degrees C. Otherwise, excessive heating may lead to chemical reactions at the interfaces within the ML mirror 220. The periodicity of each pair 223 may be affected.

Interface roughness may be influenced by the substrate 110 of the EUV mask 500. The surface roughness of the substrate 110 should be maintained at less than 0.05 nm root mean squared (RMS).

Molybdenum may oxidize so a capping layer 230 of a low atomic number material, such as Si with a thickness of 4.0 nm, may be included above the upper surface of the ML mirror 220 to stabilize the reflectance of the ML mirror 220.

If desired, Beryllium, with a Z of 4, may be used as a low-Z material 222. An ML mirror 220 including pairs 223 of alternating layers of Molybdenum and Beryllium (Mo/Be) may achieve a higher reflectance at about 11.3 nanometers. However, both Mo and Be may oxidize so a capping layer 230 may be formed from a material that will remain chemically stable within the environment of the step-and-scan imaging tool.

If desired, Ruthenium, with a Z of 44, may be used as a high-Z material 221. An ML mirror 220 including pairs 223 of alternating layers of Molydenum-Ruthenium and Beryllium (MoRu/Be) may have less intrinsic stress than Mo/Be.

The absorber 300 may have a thickness of about 30-90 nm. The absorber 300 absorbs light at the illumination wavelength of the light 410, 420 for which the EUV mask 500 may be used.

EUV light 410, 420 may be obliquely incident on the EUV mask 500 during exposure. In an embodiment of the present invention, the incident angle 412, 422 of the illumination light 410, 420 on the EUV mask 500 may be about 5 (+/−1.5) degrees away from the normal (90 degree) angle 411, 421. Consequently, a shadowing effect along the edges of the absorber 300 may affect print bias and overlay placement of features in the pattern on the wafer. An excessively thick absorber 300 may undesirably increase variation of the feature size. Using an unecessarily thick absorber 300 may also increase any asymmetry that may be inherent in the EUV mask 500 due to the oblique illumination.

An oscillating relationship results from interference between the reflected light 415 in the region 371 of the EUV mask 500 and the reflected light in the region 372 of the EUV mask 500. The phase difference between the principal light rays oscillates with half the wavelength of the incident light. Constructive and destructive interference may occur for absorber height 350 differing by only a quarter of a wavelength or about 3 nm. A variation in absorber height 350 of 3 nm may cause linewidth on the wafer to vary by about 4 nm.

According to an embodiment of the present invention, the absorber 300 may be optimized to reduce shadowing during exposure of the EUV mask 500. As shown in an embodiment of the present invention in FIG. 1, the absorber 300 may be absent over a first region 371 of the EUV mask 500 and present over a second region 372 of the EUV mask 500.

In an embodiment of the present invention, a material with a large absorption coefficient of EUV light may first be selected for the absorber 300 to reduce thickness 350 of the absorber layer 300. For an element, the absorption coefficient is proportional to the density and the atomic number, Z. Next, the thickness 350 of the absorber 300 may be selected such that the reflected light 425 from the second region 372 is 180 degrees out of phase with the reflected light 415 from the first region 371.

On the one hand, the first region 371 of the EUV mask 500 is strongly reflective from the underlying ML mirror 220 since the overlying absorber 300 is missing over the first region 371. On the other hand, the second region 372 of the EUV mask 500 is weakly reflective from the underlying ML mirror 220 despite being covered by the overlying absorber 300 since the absorber is leaky.

In an embodiment of the present invention, the light leakage in the second region 372 may be selected from a range of about 0.1-0.3%. In an embodiment of the present invention, the light leakage in the second region 372 may be selected from a range of about 0.3-1.0%. In an embodiment of the present invention, the light leakage in the second region 372 may be selected from a range of about 1.0-3.0%. In an embodiment of the present invention, the light leakage in the second region 372 may be selected from a range of about 3.0-10.0%.

The destructive interference between the reflected light 415 from the first region 371 and the reflected light 425 from the second region 372 is a periodic phenomenon so various thicknesses for the absorber 300 may be chosen. However, the minimum thickness of the absorber 300 that is consistent with sufficient contrast in printing the two regions of the EUV mask 500 should be selected. Another consideration is that the contrast between the two regions of the EUV mask 500 should be sufficient to permit linewidth measurement and defect inspection.

In an embodiment of the present invention, the thickness of the absorber 300 in the second region 372 may be reduced to 65% of the thickness that would otherwise have been required for 99.8% absorption (negligible leakage) of the incident light 420. In an embodiment of the present invention, the thickness of the absorber 300 in the second region 372 may be reduced to 50% of the thickness that would otherwise have been required for 99.8% absorption (negligible leakage) of the incident light 420. In an embodiment of the present invention, the thickness of the absorber 300 in the second region 372 may be reduced to 35% of the thickness that would otherwise have been required for 99.8% absorption (negligible leakage) of the incident light 420.

In an embodiment of the present invention, using UV light with an absorber 300 formed from Tantalum Nitride with a thickness of about 46 nm may result in a phase change of about 180 degrees and may print 30 nm lines and spaces with an aerial image contrast of about 93.0%.

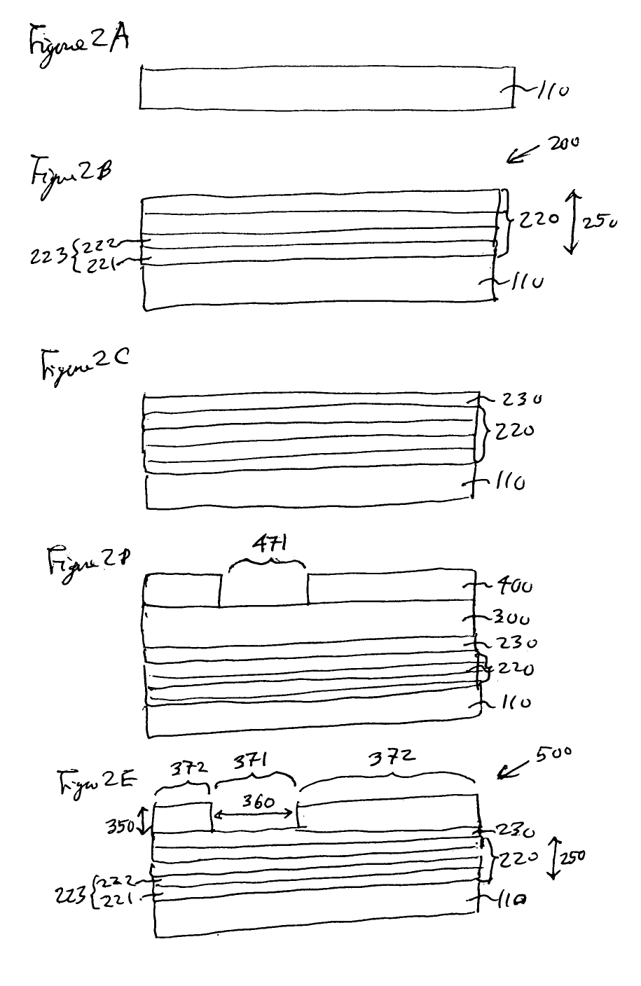

A method of forming an EUV mask 500 to reduce shadowing during exposure will be described next in FIGS. 2 A-F.

FIG. 2 A shows a robust substrate 110 with a flat and smooth upper surface. An EUV mask 500 may be used with an angle of incidence that is about 5 (+/−1.5) degrees away from the normal (90 degrees) angle from the upper surface. Such non-telecentric illumination of the EUV mask 500 may cause a change in apparent linewidth and location of features on the wafer if the upper surface of the EUV mask 500 is not sufficiently flat. The partial coherence of the illumination may also change the linewidth variation, but would not cause a pattern shift.

A glass, ceramic, or composite material with a low coefficient of thermal expansion (CTE) may be used for the substrate 110 to minimize any image displacement error during printing with the EUV mask 500. An example of a low CTE glass is ULE® which is composed of amorphous Silicon Dioxide (SiO₂) doped with about 7% Titanium Dioxide (TiO₂). ULE is a registered trademark of Corning, Inc, USA. An example of a low CTE glass-ceramic is Zerodur®. Zerodur is a registered trademark of Schott Glaswerk GmbH, Germany.

FIG. 2 B shows a mask blank 200 with a multilayer (ML) mirror 220 of 20-80 pairs 223 of alternating layers of two materials 221, 222 to achieve a high reflectance at an illumination wavelength of about 13.4 nm. The reflective material 221 may be formed from a high-Z material such as Molybdenum (Mo) with a thickness of about 2.7 nm. The transmissive material 222 may be formed from a low-Z material such as Silicon (Si) with a thickness of about 4.0 nm.

The ML mirror 220 may be formed over the substrate 110 using ion beam deposition (IBD) or DC magnetron sputtering. The thickness uniformity should be better than 0.8% across a substrate 110 formed from a 300 mm Silicon wafer.

On the one hand, ion beam deposition may result in fewer defects at an upper surface of the ML mirror 220 since any defect on the substrate 110 below tends to be smoothened over during the alternating deposition from elemental targets. As a result, the upper layers of the ML mirror 220 may be perturbed less.

On the other hand, DC magnetron sputtering may be more conformal, thus producing better thickness uniformity, but any defect on the substrate 110 may propagate up through the ML mirror 220 to its upper surface.

The reflective region 371 of the ML mirror 220, as shown in FIG. 2 E, may be difficult to repair so the mask blank 200 should have an extremely low level of defects. In particular, any defect in the mask blank 200 that may affect either magnitude or phase of EUV light may result in undesirable printing of artifacts.

Both the reflective high-Z material 221 and the transmissive low-Z material 222 in the ML mirror 220 are usually mostly amorphous or partially polycrystalline. The interface between the high-Z material 221 and the low-Z material 222 should remain chemically stable during mask fabrication and during mask exposure. Minimal interdiffusion should occur at the interfaces. Optimization of the optical properties of the ML mirror 220 requires that the individual layers 221, 222 be smooth, transitions between the different materials be abrupt, and the thickness variation across each layer be less than about 0.01 nm.

As shown in FIG. 2 C, a capping layer 230 may be formed over the ML mirror 220 in the mask blank 200 to prevent oxidation of the ML mirror 220 by the environment. The capping layer 230 may have a thickness of about 20-80 nm.

A buffer layer (not shown) may be formed over the capping layer 230. The buffer layer may act later as an etch stop layer for patterning of the overlying absorber 300. Furthermore, the buffer layer may also serve later as a sacrificial layer for focused ion beam (FIB) repair of defects in the absorber 300.

The buffer layer may have a thickness of about 20-60 nm. The buffer layer may be formed from Silicon Dioxide (SiO₂). Low temperature oxide (LTO) is often used to minimize process temperature, thus reducing interdiffusion of the materials between the alternating layers in the ML mirror 220. Other materials with similar properties may be selected for the buffer layer, such as silicon oxynitride (SiOxNy). The buffer layer may be deposited by RF magnetron sputtering. If desired, a layer of amorphous Silicon or Carbon (not shown) may be deposited prior to deposition of the buffer layer.

FIG. 2 D shows an absorber 300 that is deposited over the buffer layer (not shown) and capping layer 230. The absorber 300 should attenuate EUV light, remain chemically stable during exposure to EUV light, and be compatible with the mask fabrication process.

The absorber 300 may have a thickness of about 20-90 nm. The absorber 300 may be deposited with DC magnetron sputtering. The absorber 300 may be formed from various materials.

Various metals and alloys may be suitable for forming the absorber 300. Examples include Aluminum (Al), Aluminum-Copper (AlCu), Chromium (Cr), Tantalum (Ta), Titanium (Ti), and Tungsten (W).

The absorber 300 may also be formed, entirely or partially, out of borides, carbides, nitrides, or silicides of certain metals. Examples include Nickel Silicide (NiSi), Tantalum Boride (TaB), Tantalum Nitride (TaN), Tantalum Silicide (TaSi), Tantalum Silicon Nitride (TaSiN), and Titanium Nitride (TiN).

FIG. 2 D further shows a radiation-sensitive layer, such as a photoresist 400, that may be coated over the absorber 300, exposed, and developed to create an opening 471. The photoresist 400 may have a thickness of about 90-270 nm. A chemically amplified resist (CAR) may be used. Deep ultraviolet (DUV) light or an electron beam (e-beam) may be used to pattern the features in the photoresist 400.

After measurement of the opening 471 in the photoresist 400, the pattern may be transferred from the photoresist 400 into a region 371 in the absorber 300 as shown in FIG. 2 E. Reactive ion etch (RIE) may be used. For example, a Tantalum (Ta) absorber 300 may be dry etched with a gas that contains Chlorine, such as Cl₂ and BCl₃. In some cases, Oxygen (O₂) may be included.

The etch rate and the etch selectivity may depend on power, pressure, and substrate temperature within the reactor. As needed, a hard mask process may be used to transfer the pattern from the photoresist 400 to a hard mask (not shown) and then to the absorber 300.

The buffer layer (not shown) over the capping layer 230 serves as an etch stop layer to produce a good etch profile in the overlying absorber 300. The buffer layer also protects the underlying capping layer 230 and the ML mirror 220 from etch damage.

After removing the photoresist 400, the linewidth and placement accuracy of pattened features may be measured. Then, defect inspection may be done and defect repair of the absorber 300 may be performed as needed. The buffer layer further serves as a sacrificial layer for focused ion beam (FIB) repair of clear and opaque defects associated with the absorber 300.

The buffer layer may increase diffraction in the ML mirror 220 of the EUV mask 500 during exposure. The resulting reduction in contrast may degrade CD control of the features printed on a wafer. Consequently, the buffer layer may be removed by dry etch, wet etch, or a combination of the two processes. For example, the buffer layer may be dry etched with a gas that contains Fluorine, such as CF₄ or C₂F₆. Oxygen (O₂) and a carrier gas, such as Argon (Ar), may be included.

The buffer layer may be wet etched if it is very thin since any undercut of the absorber 400 would then be small. For example, a buffer layer formed from Silicon Dioxide may be etched with an aqueous solution of about 3-5% hydrofluoric (HF) acid. The dry etch or wet etch selected to remove the buffer layer must not damage the absorber 300, the capping layer 230, or the ML mirror 220.

Many embodiments and numerous details have been set forth above in order to provide a thorough understanding of the present invention. One skilled in the art will appreciate that many of the features in one embodiment are equally applicable to other embodiments. One skilled in the art will also appreciate the ability to make various equivalent substitutions for those specific materials, processes, dimensions, concentrations, etc. described herein. It is to be understood that the detailed description of the present invention should be taken as illustrative and not limiting, wherein the scope of the present invention should be determined by the claims that follow.

Thus, we have described an EUV mask to reduce shadowing during exposure and a process for fabricating such an EUV mask.

We claim:

1. A method of forming a mask comprising:
providing a substrate;
forming a multilayer mirror for EUV light over said substrate;
forming a leaky absorber for said EUV light over said multilayer mirror; and
patterning said leaky absorber into a first region that is strongly reflective and a second region that is weakly reflective.

2. The method of claim 1 wherein a capping layer is further formed over said multilayer mirror in said first region and said second region.

3. The method of claim 2 wherein a buffer layer is further formed over said capping layer in said second region.

4. The method of claim 1 wherein said multilayer mirror comprises a scattering layer and a spacing layer.

5. A method of forming an EUV mask comprising:
providing a substrate;
forming a mirror over said substrate, said mirror comprising:
alternating layers of a reflective material and a transmissive material;
forming a leaky absorber over said mirror, said leaky absorber shifting phase of incident light by 180 degrees; and
removing said leaky absorber in a first region to uncover said mirror.

6. The method of claim 5 wherein a capping layer is further formed over said mirror.

7. The method of claim 5 wherein a buffer layer is further formed below said leaky absorber.

8. The method of claim 5 wherein said leaky absorber reflects about 1.0-3.0% of incident light.

9. An EUV mask comprising:
a substrate;
a multilayer mirror disposed over said substrate, said multilayer mirror having a first region and a second region; and
a leaky absorber disposed over said second region of said multiplayer mirror, said leaky absorber shifting phase of incident light by 180 degrees.

10. The mask of claim 9 wherein a capping layer is further disposed over said multilayer mirror in said first region and said second region.

11. The mask of claim 9 wherein a buffer layer is further disposed below said leaky absorber.

12. The mask of claim 9 wherein said second region reflects about 1.0-3.0% of incident light.

13. A reflective mask for oblique incident light comprising:
a substrate;
a multilayer mirror disposed over said substrate, said multilayer mirror having a first region and a second region; and
an absorber disposed over said second region of said multilayer mirror wherein said absorber permits said multilayer mirror to reflect about 1.0-3.0% of said oblique incident light with a phase shift of 180 degrees.

14. The mask of claim 13 wherein a capping layer is further disposed over said multilayer in said first region and said second region.

15. The mask of claim 13 wherein a buffer layer is further disposed below said absorber.

16. The mask of claim 13 wherein said reflective mask for oblique incident light reduces shadowing.

17. The mask of claim 13 wherein said absorber comprises Tantalum Nitride with a thickness of about 46 nm.

18. The mask of claim 13 wherein 30 nm lines and spaces may be printed.
